(19) United States
(12) Patent Application Publication
(10) Pub. No.: US 2010/0288974 A1
(43) Pub. Date: Nov. 18, 2010

(54) ELECTROLUMINESCENT POLYMERS AND USE THEREOF

(75) Inventors: Arne Buesing, Frankfurt Am Main (DE); Rene Scheurich, Gross-Zimmern (DE); Niels Schulte, Kelkheim (DE); Aurelie Ludemann, Frankfurt (DE)

Correspondence Address: CONNOLLY BOVE LODGE & HUTZ, LLP, P O BOX 2207, WILMINGTON, DE, 19899, US

(73) Assignee: MERCK PATENT GMBH, Darmstadt (DE)

(21) Appl. No.: 12/063,363

(22) PCT Filed: Jul. 19, 2006
(86) PCT No.: PCT/EP2006/007105

§ 371 Date: May 17, 2010

(30) Foreign Application Priority Data
Aug. 10, 2005 (DE) 10 2005 037 734.3

(51) Int. Cl. C09K 11/06; C08G 61/12; C07C 25/18

(52) U.S. Cl. 252/301.35; 528/397; 570/183

(57) ABSTRACT

The present invention relates to electroluminescent polymers which comprise at least 5 mol % of structural units of the formula (1), and to the use thereof. The polymers according to the invention exhibit improved efficiency and a longer lifetime, in particular on use in polymeric organic light-emitting diodes.

The present invention relates to polymers, preferably electroluminescent polymers, which comprise at least 5 mol % of structural units of the formula (1), and to the use thereof. The polymers according to the invention exhibit improved efficiency and a longer lifetime, in particular on use in polymeric organic light-emitting diodes.

Broadly based research on the commercialisation of display and illumination elements based on polymeric (organic) light-emitting diodes (PLEDs) has been under way for more than ten years. This development was prompted by the basic developments disclosed in WO 90/13148 A1. A first, albeit simple, product (a small display in a shaver from PHILIPS N.V.) has also recently become available on the market. However, significant improvements in the materials used are still necessary in order to make these displays a true competitor to the liquid-crystal displays (LCDs) which currently dominate the market.

For the production of all three emission colours, it is necessary to copolymerise certain comonomers into the corresponding polymers (cf., for example, WO 00/46321 A1, WO 03/020790 A2 and WO 02/077060 A1). In this way, starting from a blue-emitting base polymer (“backbone”), it is then generally possible to produce the two other primary colours red and green.

Various classes of material have already been proposed or developed as polymers for full-colour display elements. Thus, both, for example, polyfluorene derivatives and also polyspirobifluorene, polydihydrophenanthrene and polyindenofluorene derivatives come into consideration. Polymers which comprise a combination of the said structural units have also already been proposed. In addition, polymers which comprise poly-paraphenylene (PPP) as structural unit are also being employed.

Some of the polymers in accordance with the prior art already exhibit good properties on use in PLEDs. In spite of the advances already achieved, however, these polymers do not yet meet the requirements made of them for high-quality applications.

In particular, the lifetime of the green- and especially of the blue-emitting polymers is inadequate for many applications. The same applies to the efficiency of the red-emitting polymers.

Surprisingly, it has now been found that a novel class of polymers has very good properties which are superior to the above-mentioned prior art. The present invention therefore relates to these polymers and to the use thereof in PLEDs. The novel structural units are particularly suitable as polymer backbone, but, depending on the substitution pattern, also as hole conductors, electron conductors and/or emitters.

The use of phenanthrenes in electroluminescent polymers is known and is disclosed, for example, in WO 02/077060 A1, WO 03/020790 A2 and DE 10337346 A1. However, it is only listed in general terms therein that these structural elements, as well as a large number of other monomers, may be present as possible further elements in addition to the actual polymer backbone. Particular advantages of these units are not described. In addition, it is only described in very general terms that they may be substituted by non-aromatic substituents or unsubstituted. However, the use of unsubstituted phenanthrene units results in insoluble polymers, meaning that these units can be used at most in a small proportion. However, it is not evident from these disclosures which substituents are particularly suitable and in what positions of the phenanthrene unit these substituents should preferably be bonded. It is equally unclear that the novel structural units are particularly suitable for being employed in a larger proportion in the polymer since they are only mentioned in the prior art as comonomers in comparatively small proportions. It is thus not evident to the person skilled in the art how these units can beneficially be used in electroluminescent polymers. The general disclosure of phenanthrene units should therefore be regarded as a chance disclosure.

The substitution of the phenanthrene units in the 9- or 9,10-position and the linking in the polymer in the 3,6-position have, surprisingly, proven particularly suitable compared with substitution in other positions of the phenanthrene unit. This preference may be due to the particularly good synthetic accessibility of the units substituted in these positions, but also to the better optical and electronic properties.

The invention relates to polymers comprising at least 5 mol %, preferably at least 10 mol %, particularly preferably at least 30 mol % and in particular at least 50 mol %, of units of the formula (1)

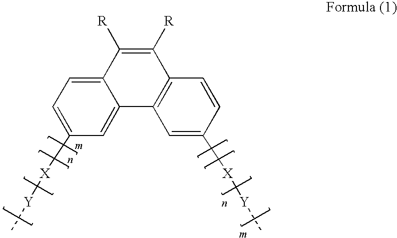

in which
R on each occurrence, identically or differently, is H, a straight-chain, branched or cyclic alkyl chain having 1 to 40 C atoms, which may be substituted by R¹ and in which, in addition, one or more non-adjacent C atoms may be replaced by ═N—R¹, —O—, —S—, —O—CO—O—, —CO—O—, —CR¹═CR¹— or preferably with the proviso that the hetero atoms are not bonded directly to the phenanthrene unit, and in which, in addition, one or more H atoms may be replaced by F, Cl, Br, I or CN, or an aromatic or heteroaromatic ring system having 2 to 40 C atoms, which, in addition, may be substituted by one or more radicals R¹; the two radicals R here may also form a further mono- or polycyclic, aromatic or aliphatic ring system with one another; preferably with the proviso that at least one of the two radicals R is not equal to H;
X on each occurrence, identically or differently, is —CR¹═CR¹—, —C≡C— or ═N—Ar—;
Y on each occurrence, identically or differently, is a divalent aromatic or heteroaromatic ring system having 2 to 40 C atoms, which may be unsubstituted or substituted by one or more radicals R¹;
R¹ on each occurrence, identically or differently, is H, a straight-chain, branched or cyclic alkyl or alkoxy chain having 1 to 22 C atoms, in which, in addition, one or more non-adjacent C atoms may be replaced by ═N—R², —O—, —S—, —O—CO—O—, —CO—O—, —CR²═CR²— or —C≡C— and in which, in addition, one or more H atoms may be replaced by F, Cl, Br, I or ON, or an aryl, heteroaryl, aryloxy or heteroaryloxy group having 5 to 40 C atoms, which, in addition, may be substituted by one or more non-aromatic radicals R²; two or more of the radicals R¹ here may also form a ring system with one another and/or with R; or F, Cl, Br, I, CN, N(R²)₂, Si(R²)₃ or B(R²)₂;
R² on each occurrence, identically or differently, is H or an aliphatic or aromatic hydrocarbon radical having 1 to 20 C atoms;
Ar on each occurrence, identically or differently, is a monovalent aromatic or heteroaromatic ring system having 2 to 40 C atoms, which may be unsubstituted or substituted by R¹;
n on each occurrence, identically or differently, is 0 or 1;
m on each occurrence, identically or differently, is 0, 1 or 2; and
   the dashed bond in formula (1) and also in all other formulae denotes the link in the polymer. It is not intended to represent a methyl group here.

Although evident from the description, it should again be explicitly pointed out here that the structural units of the formula (1) may be asymmetrically substituted, i.e. that different substituents R or R¹ may be present on one unit, or that the substituents X and Y, if present, may be different or also only occur on one side.

For the purposes of the present invention, an aromatic or heteroaromatic ring system is intended to be taken to mean a system which does not necessarily contain only aromatic or heteroaromatic groups, but instead in which, in addition, a plurality of aromatic or heteroaromatic groups may be interrupted by a short non-aromatic unit (<10% of the atoms other than H, preferably <5% of the atoms other than H), such as, for example, sp³-hybridised C, O, N, etc. Thus, for example, systems such as 9,9′-spirobifluorene, 9,9-diarylfluorene, triarylamine, etc., are also intended to be understood as aromatic ring systems.

One aspect of the invention relates to conjugated polymers. A further aspect of the invention relates to non-conjugated polymers. Yet a further aspect of the invention relates to partially conjugated polymers. Preference is given to conjugated or partially conjugated polymers.

For the purposes of this invention, conjugated polymers are polymers which principally contain sp²-hybridised carbon atoms, which, in addition, may be replaced by corresponding hetero atoms, in the main chain. In the simplest case, this means the alternating presence of double and single bonds in the main chain. Principally it means that naturally occurring defects which result in interruptions to the conjugation do not invalidate the term “conjugated polymer”. Furthermore, the term conjugated is likewise used in this application text if, for example, arylamine units and/or certain heterocycles (i.e. conjugation via N, O or S atoms) and/or organometallic complexes (i.e. conjugation via the metal atom) are located in the main chain. By contrast, units such as, for example, simple alkyl bridges, (thio)ether, ester, amide or imide links are unambiguously defined as non-conjugated segments. A partially conjugated polymer is intended to be taken to mean a polymer in which relatively long conjugated sections in the main chain are interrupted by non-conjugated sections, or which contains relatively long conjugated sections in the side chains of a polymer which is non-conjugated in the main chain.

The polymers according to the invention may also comprise further structural elements in addition to the units of the formula (1). These are, inter alia, those as disclosed and extensively listed in WO 02/077060 A1 and in DE 10337346 A1. These are regarded as part of the present invention by way of reference. The further structural units may originate, for example, from the following classes:
Group 1: units which increase the hole-injection and/or -transport properties of the polymers;
Group 2: units which increase the electron-injection and/or -transport properties of the polymers;
Group 3: units which have combinations of individual units from group 1 and group 2;
Group 4: units which modify the emission characteristics to such an extent that electrophosphorescence may be obtained instead of electrofluorescence;
Group 5: units which improve the transition from the so-called singlet state to the triplet state;
Group 6: units which influence the morphology and/or emission colour of the resultant polymers;
Group 7: units which are typically used as backbone.

Preferred polymers according to the invention are those in which at least one structural element has charge-transport properties, i.e. which comprise units from groups 1 and/or 2.

Structural elements from group 1, which have hole-transport properties, are for example, triarylamine, benzidine, tetraaryl-para-phenylenediamine, triarylphosphine, phenothiazine, phenoxazine, dihydrophenazine, thianthrene, dibenzo-para-dioxin, phenoxathiyne, carbazole, azulene, thiophene, pyrrole and furan derivatives and further O-, S- or N-containing heterocycles with a high HOMO (HOMO=highest occupied molecular orbital). These arylamines and heterocycles preferably result in an HOMO in the polymer of greater than −5.8 eV (against vacuum level), particularly preferably greater than −5.5 eV.

Structural elements from group 2, which have electron-transport properties, are, for example, pyridine, pyrimidine, pyridazine, pyrazine, oxadiazole, quinoline, quinoxaline and phenazine derivatives, but also triarylboranes and further O-, S- or N-containing heterocycles having a low LUMO (LUMO=lowest unoccupied molecular orbital). These units in the polymer preferably result in an LUMO of less than −2.7 eV (against vacuum level), particularly preferably less than −3.0 eV.

It may be preferred for the polymers according to the invention to comprise units from group 3 in which structures which increase the hole mobility and the electron mobility (i.e. units from groups 1 and 2) are bonded directly to one another. Some of these units may serve as emitters and shift the emission colour into the green, yellow or red. Their use is thus suitable, for example, for the production of other emission colours from originally blue-emitting polymers.

Structural units in accordance with group 4 are those which are able to emit light from the triplet state with high efficiency even at room temperature, i.e. exhibit electrophosphorescence instead of electrofluorescence, which frequently causes an increase in the energy efficiency. Suitable for this purpose are firstly compounds which contain heavy atoms having an atomic number of greater than 36. Preference is given to compounds which contain d- or f-transition metals which satisfy the above-mentioned condition. Particular preference is given here to corresponding structural units which contain elements from groups 8 to 10 (Ru, Os, Rh, Ir, Pd, Pt). Suitable structural units for the polymers according to the invention here are, for example, various complexes as described, for example, in WO 02/068435 A1, DE 10116962 A1, EP 1239526 A2 and DE 10238903 A1. Corresponding monomers are described in WO 02/068435 A1 and DE 10350606 A1.

Structural elements from group 5 are those which improve the transition from the singlet state to the triplet state and which, employed in support of the structural elements from group 4, improve the phosphorescence properties of these structural elements. Suitable for this purpose are, in particular, carbazole and bridged carbazole dimer units, as described in DE 10304819 A1 and DE 10328627 A1. Also suitable for this purpose are ketones, phosphine oxides, sulfoxides, sulfones, silane derivatives and similar compounds, as described in DE 10349033 A1.

Structural elements from group 6, which influence the morphology and/or emission colour of the polymers, are, besides those mentioned above, those which have at least one further aromatic or another conjugated structure which do not fall under the above-mentioned groups, i.e. which have only little effect on the charge-carrier mobilities, which are not organometallic complexes or which have no influence on the singlet-triplet transition. Structural elements of this type may influence the morphology and/or emission colour of the resultant polymers. Depending on the unit, they can therefore also be employed as emitters. Preference is given here to aromatic structures having 6 to 40 C atoms or also tolan, stilbene or bisstyrylarylene derivatives, each of which may be substituted by one or more radicals R¹. Particular preference is given here to the incorporation of 1,4-phenylene, 1,4-naphthylene, 1,4- or 9,10-anthrylene, 1,6-, 2,7- or 4,9-pyrenylene, 3,9- or 3,10-perylenylene, 4,4′-biphenylylene, 4,4″-terphenylylene, 4,4′-bi-1,1″-naphthylylene, 4,4′-tolanylene, 4,4′-stilbenzylene or 4,4″-bisstyrylarylene derivatives.

Structural elements from group 7 are units which contain aromatic structures having 6 to 40 C atoms which are typically used as polymer backbone. These are, for example, 4,5-dihydropyrene derivatives, 4,5,9,10-tetrahydropyrene derivatives, fluorene derivatives, 9,9′-spirobifluorene derivatives, 9,10-dihydrophenanthrene derivatives, 5,7-dihydrodibenzooxepine derivatives and cis- and trans-indenofluorene derivatives. However, since the proportion of units of the formula (1) is very particularly preferably at least 50 mol %, these structural elements from group 7 here are not preferably employed as the principal polymer backbone, but instead at most as backbone which is present in a smaller proportion. Preference is given to polymers according to the invention which simultaneously, besides structural units of the formula (1), additionally comprise one or more units selected from groups 1 to 7. It may likewise be preferred for more than one structural unit from a group to be present simultaneously.

The proportion of units of the formula (1) is preferably at least 10 mol %, particularly preferably at least 30 mol % and in particular at least 50 mol %. This preference applies in particular if the units of the formula (1) are the polymer backbone. In the case of other functions, other proportions may be preferred, for example a proportion in the order of 5 to 20 mol % in the case of the hole conductor or emitter in an electroluminescent polymer. For other applications, for example for organic transistors, the preferred proportion may again be different, for example up to 100 mol % in the case of hole- or electron-conducting units.

Preference is given to polymers according to the invention which, besides structural units of the formula (1), also comprise at least one structural unit from the above-mentioned groups. At least two structural units are particularly preferably from different classes of those mentioned above. If present, the proportion of these structural elements is preferably in each case at least 5 mol %, particularly preferably in each case at least 10 mol %. In particular, one of these structural units is selected from the group of hole-conducting units and the other group is an emitting unit, where these two functions (hole conduction and emission) may also be taken on by the same unit.

However, a smaller proportion of the emitting units, in particular green- and red-emitting units, may also be preferred, for example for the synthesis of white-emitting copolymers. The way in which white-emitting copolymers can be synthesised is described in detail in DE 10343606 A1.

The polymers according to the invention generally comprise 10 to 10,000, preferably 50 to 5000 and particularly preferably 50 to 2000 recurring units.

The requisite solubility of the polymers is ensured, inter alia, by the substituents R or R¹ on the units of the formula (1) and where appropriate on other units present. If further substituents are present, these may also contribute to the solubility.

In order to ensure adequate solubility, it is preferred for on average at least 2 non-aromatic C atoms to be present in the substituents per recurring unit. Preference is given here to at least 4 and particularly preferably at least 8 C atoms. In addition, individual C atoms of these may be replaced by O or S. However, it is entirely possible for this to mean that a certain proportion of recurring units does not carry any further non-aromatic substituents.

In order to avoid impairing the morphology of the film, it is preferred to have no long-chain substituents having more than 12 C atoms in a linear chain, particularly preferably none having more than 8 C atoms and in particular none having more than 6 C atoms.

Non-aromatic C atoms are, as, for example, in the description for R and R¹ in respect of formula (1), present in corresponding straight-chain, branched or cyclic alkyl or alkoxy chains.

Preference is given to polymers according to the invention in which, for units of the formula (1),
R on each occurrence, identically or differently, is a straight-chain, branched or cyclic alkyl chain having 2 to 25 C atoms, in which, in addition, one or more non-adjacent C atoms may be replaced by ═N—R¹, —O—, —S—, —O—CO—O—, —CO—O—, —CH═CH— or —C≡C—, preferably with the proviso that the hetero atoms are not bonded directly to the phenanthrene unit, and in which, in addition, one or more H atoms may be replaced by F or CN, or an aromatic or heteroaromatic group having 4 to 20 C atoms, which, in addition, may be substituted by one or more non-aromatic radicals R¹; the two radicals R here may together also form a further mono- or polycyclic, aromatic or aliphatic ring system;
X on each occurrence, identically or differently, is —CR¹═CR¹—, or ═N—Ar—;
Y on each occurrence, identically or differently, is a divalent aromatic or heteroaromatic ring system having 4 to 30 C atoms, which may be substituted by one or more radicals R¹;
R¹ on each occurrence, identically or differently, is H, a straight-chain, branched or cyclic alkyl or alkoxy chain having 1 to 22 C atoms, in which, in addition, one or more non-adjacent C atoms may be replaced by ═N—R², —O—, —S—, —O—CO—O—, —CO—O—, —CH═CH— or —C≡C— and in which, in addition, one or more H atoms may be replaced by F or CN, or an aryl, heteroaryl, aryloxy or heteroaryloxy group having 5 to 40 C atoms, which, in addition, may be substituted by one or more non-aromatic radicals R²; two or more of the radicals R¹ here may also form a mono- or polycyclic, aliphatic or aromatic ring system with one another and/or with R; or F, Cl, Br, I, CN, N(R²)₂, Si(R²)₃ or B(R²)₂;
Ar on each occurrence, identically or differently, is a monovalent aromatic or heteroaromatic ring system having 4 to 30 C atoms, which may be unsubstituted or substituted by R¹;
m on each occurrence, identically or differently, is 0 or 1; and
   the other symbols and indices are as defined above in relation to formula (1).

Particular preference is given to polymers according to the invention in which, for units of the formula (1),
R on each occurrence, identically or differently, is a straight-chain, branched or cyclic alkyl chain having 4 to 20 C atoms, particularly preferably a branched alkyl chain, in which, in addition, one or more non-adjacent C atoms may be replaced by ═N—R¹, —O—, —S—, —O—CO—O—, —CO—O—, —CH═CH— or —C≡C—, preferably with the proviso that these are not directly adjacent to the phenanthrene unit, and in which, in addition, one or more H atoms may be replaced by F; the two radicals R here may together also form a further mono- or polycyclic ring system;
X on each occurrence, identically or differently, is —CH═CH—, —C≡C— or ═N—Ar—;
Y on each occurrence, identically or differently, is a divalent aromatic or heteroaromatic ring system having 6 to 25 C atoms, which may be substituted by one or more non-aromatic radicals R¹;
Ar on each occurrence, identically or differently, is a monovalent aryl or heteroaryl group having 4 to 20 C atoms, which may be substituted by non-aromatic radicals R¹;
m on each occurrence, identically or differently, is 0 or 1; and
   the other symbols and indices are as defined above.

The preference for aliphatic radicals R may be due to the still better solubility of the resultant polymers and the better synthetic accessibility.

Depending on the substitution pattern, the units of the formula (1) are particularly suitable for various functions in the polymer. Thus, these units can preferably be employed as (electron-conducting) polymer backbone, as hole conductors or as emitters. Which compounds are particularly suitable for which function is determined in particular by the substituents X and Y. The substituents R have a less pronounced influence on the electronic properties of the units of the formula (1).

Thus, for use as polymer backbone, it is preferred that

n on each occurrence is equal to 0,
i.e. it is a purely aromatic structural unit.
For use of units of the formula (1) as hole-transporting units, it is preferred that
n on each occurrence, identically or differently, is 0 or 1, where at least one n=1;
m on each occurrence, identically or differently, is 0, 1 or 2, where m is not equal to 0 if the corresponding n=1;
X on each occurrence is ═N—Ar—;
   i.e. these are triarylamine derivatives of phenanthrene.

For use of units of the formula (1) as emitters, it is preferred that
n on each occurrence, identically or differently, is 0 or 1, where at least one n=1;
m on each occurrence, identically or differently, is 0, 1 or 2, where m is not equal to 0 if the corresponding n=1;
X on each occurrence, identically or differently, is —CR¹═CR¹—, —C≡C— or ═N—Ar—, where at least one X is equal to —CR¹═CR¹— or —C≡C—,
   i.e. these are diarylvinyiene or diarylacetylene derivatives in the broadest sense, which may also additionally contain triarylamine units.

Preference is furthermore given to units of the formula (1) which are symmetrically substituted in the 9,10-positions of the phenanthrene units. This preference is due to the better synthetic accessibility of the monomers. It is thus preferred that all R in a unit of the formula (1) are identical and particularly preferably are also identically substituted. This preference does not exclude the substituents X and Y from occurring only on one side or also being different.

Examples of preferred units of the formula (1) are the following structures (S1) to (S33), where the link in the polymer in each case takes place via the 3,6-positions of the phenanthrene units, as indicated by the dashed bonds. For reasons of clarity, possible substituents are generally not shown or not shown everywhere. Alkyl here generally stands for an aliphatic alkyl group, aryl for an aromatic or heteroaromatic system, as described for R. Structures (S1) to (S18) here are examples of backbone units, structures (S19) to (S30) are examples of emitting units and structures (S31) to (S33) are examples of hole-conducting units.

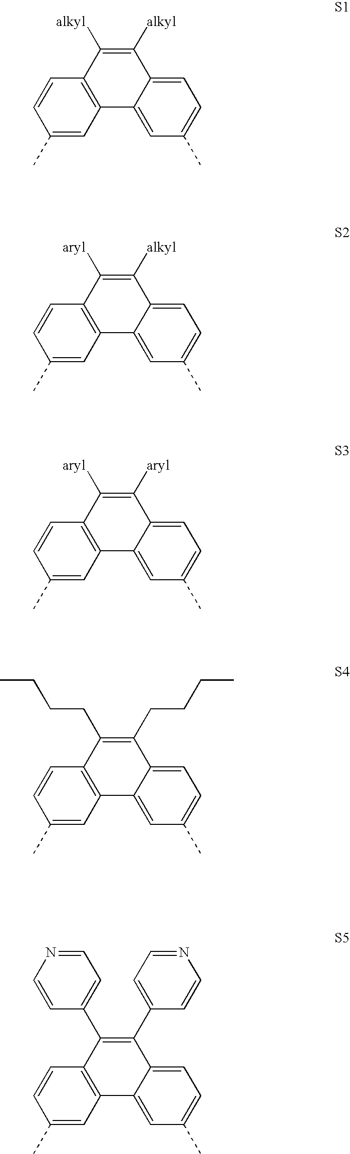

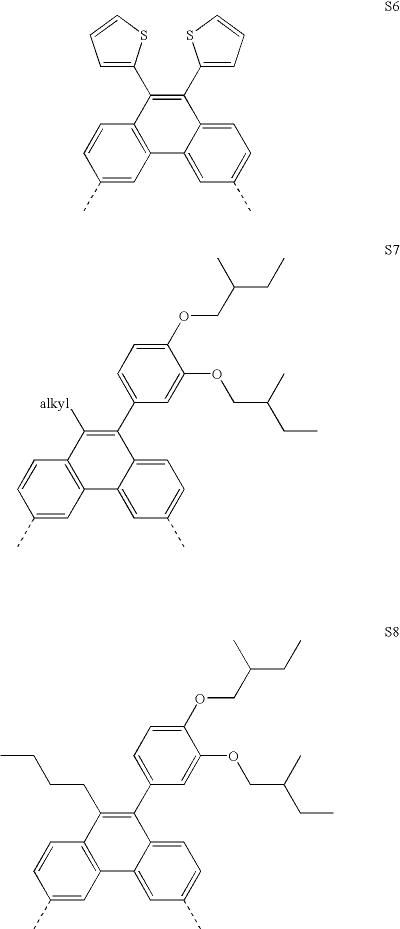

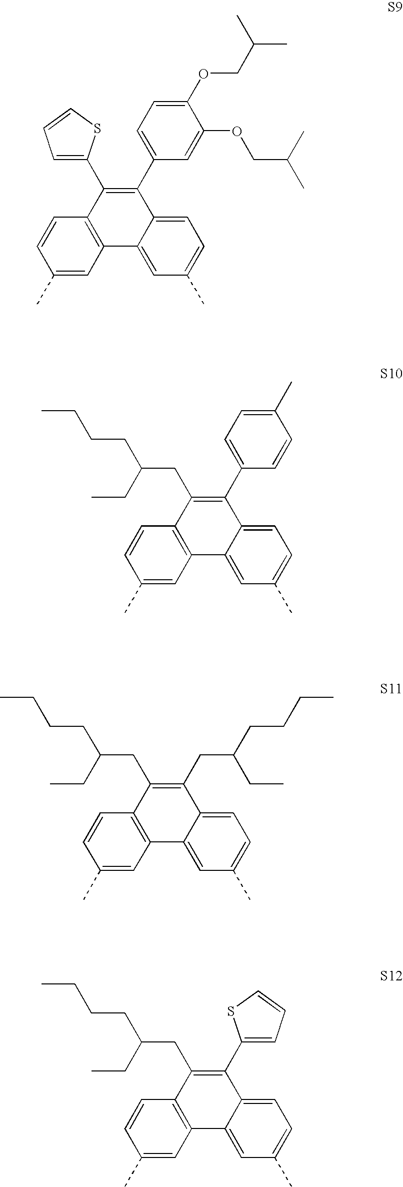

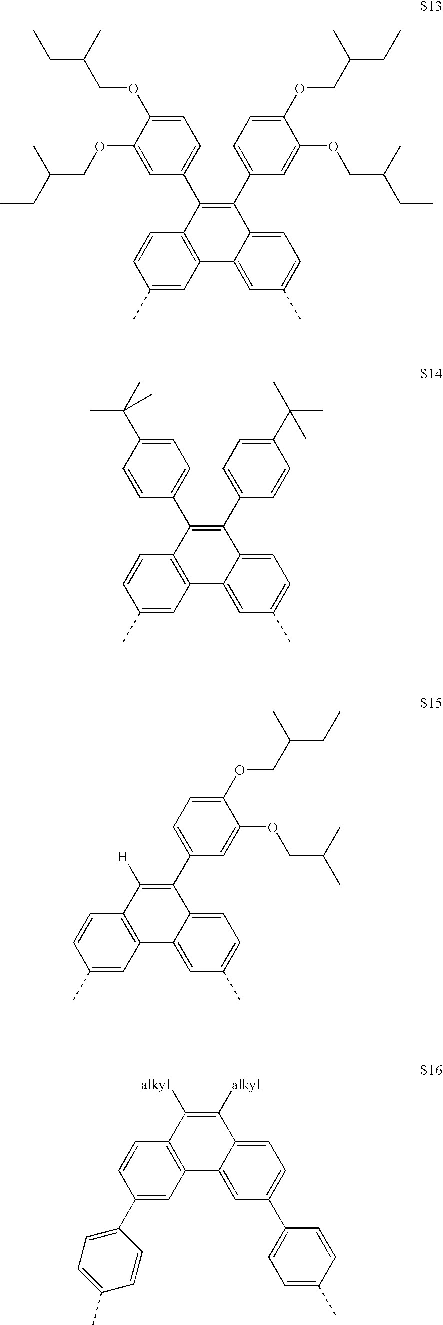

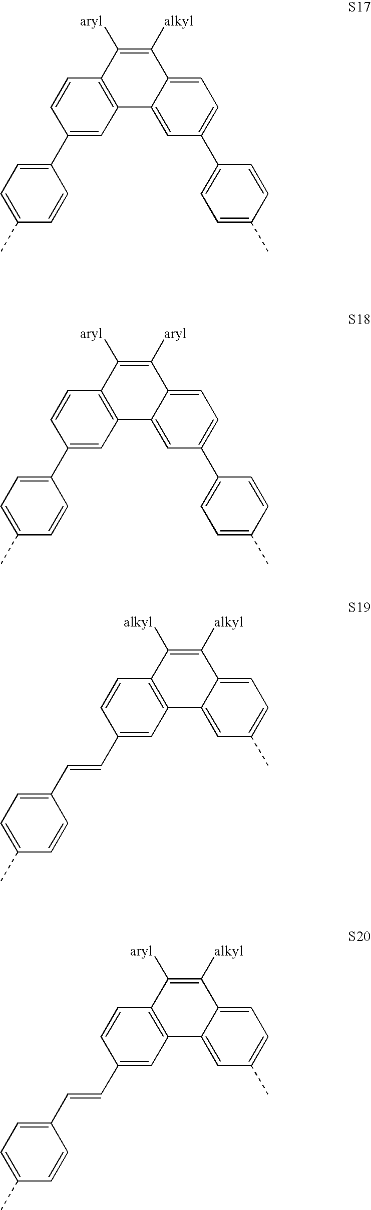

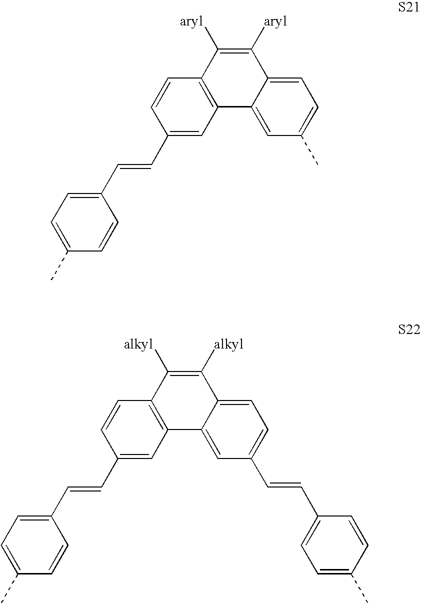

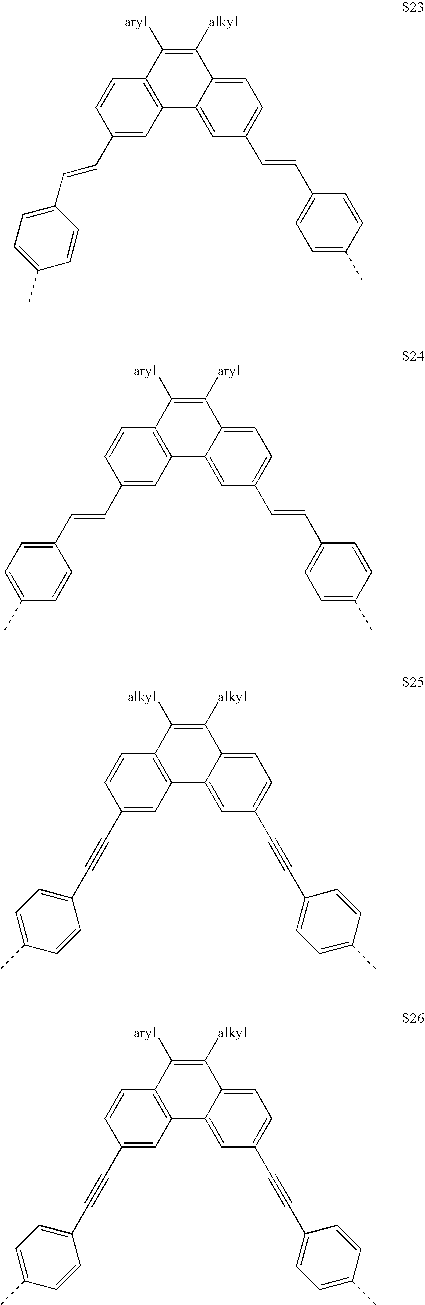

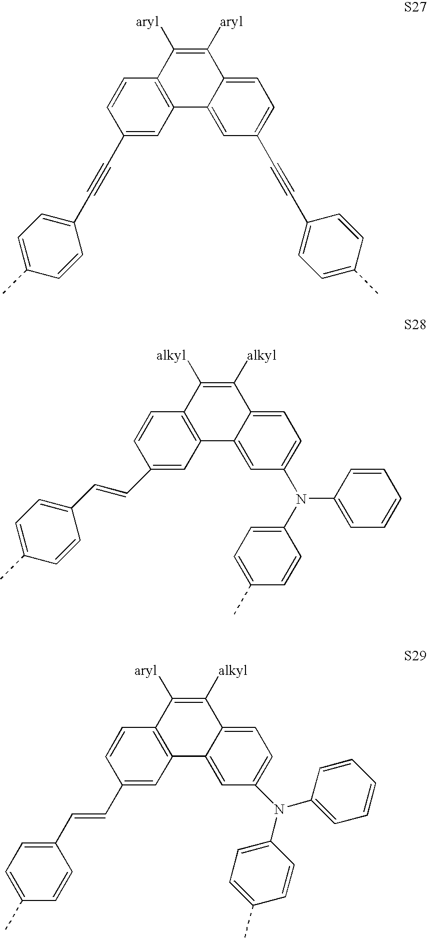

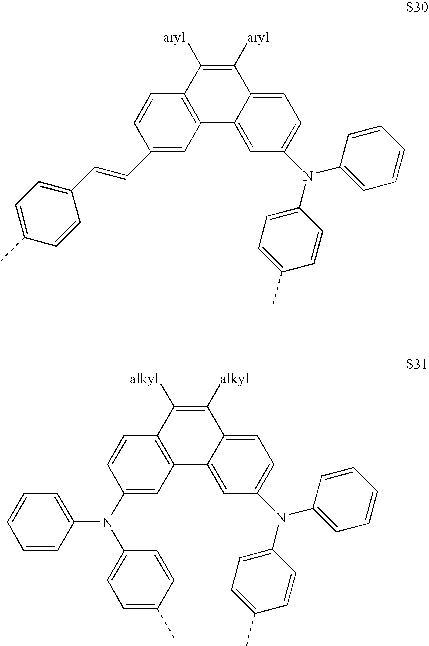

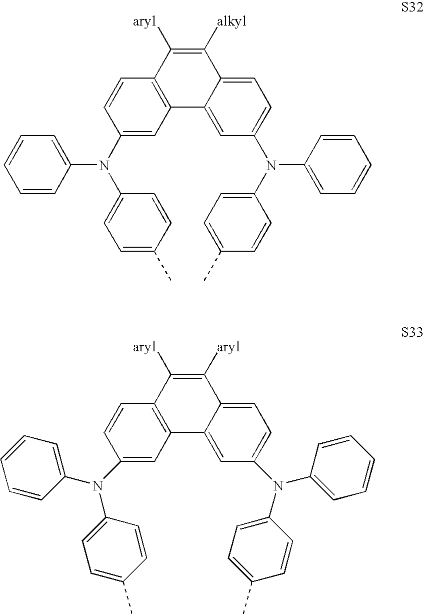

The polymers according to the invention are either homopolymers or copolymers. Besides one or more structures of the formula (1), copolymers according to the invention may potentially comprise one or more further structures, for example from the above-mentioned groups 1 to 7.

The copolymers according to the invention can have random, alternating or block-like structures or also have a plurality of these structures alternating. The way in which copolymers having block-like structures can be obtained is described in detail, for example, in DE 10337077 A1. This laid-open specification is incorporated into the present application by way of reference.

The use of a plurality of different structural elements enables properties such as solubility, solid-phase morphology, colour, charge-injection and -transport properties, temperature stability, electro-optical characteristics, etc., to be adjusted.

The polymers according to the invention are generally prepared by polymerisation of one or more types of monomer, at least one monomer of which results in units of the formula (1) in the polymer. There are in principle many corresponding polymerisation reactions. However, a few types which result in C—C or C—N links have proven particularly successful here:

(A) SUZUKI polymerisation;
(B) YAMAMOTO polymerisation;
(C) STILLE polymerisation;
(D) HARTWIG-BUCHWALD polymerisation.

The way in which the polymerisation can be carried out by these methods and the way in which the polymers can be separated off from the reaction medium and purified are described in detail, for example, in DE 10249723 A1.

Monomers which result in structural units of the formula (1) in the polymers according to the invention are phenanthrene derivatives which are suitably substituted in the 9- and/or 10-position and have suitable functionalities in the 3,6-position (or in a suitable position on Y, if present) which allow this monomer unit to be incorporated into the polymer.

Monomers which result in units of the formula (1) in the polymer are novel and are therefore likewise a subject-matter of the present invention.

The invention therefore furthermore relates to compounds of the formula (2)

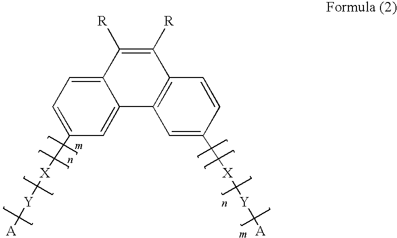

which are characterised in that the two functional groups A, identically or differently, copolymerise under conditions of the C—C or C—N linking reactions, where the other symbols and indices have the same meaning as in relation to formula (1).

A is preferably selected from Cl, Br, I, O-tosylate, O-triflate, O—SO₂R², B(OR²)₂ and Sn(R²)₃, particularly preferably from Br, I and B(OR²)₂, where R² has the same meaning as described above and where two or more radicals R² may also form a ring system with one another.

The C—C linking reactions are preferably selected from the group of the SUZUKI coupling, the YAMAMOTO coupling and the STILLE coupling; the C—N linking reaction is preferably a HARTWIG-BUCHWALD coupling.

For bifunctional monomeric compounds of the formula (2), the same preference applies as described above for the structural units of the formula (1).

It may be preferred to use the polymer according to the invention not as the pure substance, but instead as a blend together with any desired further polymeric, oligomeric, dendritic or low-molecular-weight substances. These may improve, for example, the electronic properties, influence the transfer from the singlet state to the triplet state or themselves emit light from the singlet state or from the triplet state. However, electronically inert substances may also be appropriate in order, for example, to influence the morphology of the polymer film formed or the viscosity of polymer solutions. The present invention therefore also relates to blends of this type.

The invention furthermore relates to solutions and formulations comprising one or more polymers or blends according to the invention in one or more solvents. The way in which polymer solutions can be prepared is described, for example, in WO 02/072714 A1, WO 03/019694 A2 and the literature cited therein. These solutions can be used in order to produce thin polymer layers, for example by surface-coating methods (for example spin coating) or printing methods (for example ink-jet printing).

The polymers according to the invention can be used in PLEDs. These comprise cathode, anode, emission layer and optionally further layers, such as, for example, preferably a hole-injection layer and optionally an interlayer between the hole-injection layer and the emission layer. The way in which PLEDs can be produced is described in detail as a general process in DE 10304819 A1, which should be adapted correspondingly for the individual case.

As described above, the polymers according to the invention are very particularly suitable as electroluminescent materials in the PLEDs or displays produced in this way.

For the purposes of the invention, electroluminescent materials are taken to mean materials which can be used as active layer in a PLED. Active layer means that the layer is capable of emitting light on application of an electric field (light-emitting layer) and/or that it improves the injection and/or transport of the positive and/or negative charges (charge-injection or charge-transport layer). It may also be an interlayer between a hole-injection layer and an emission layer.

The invention therefore also relates to the use of a polymer according to the invention in a PLED, in particular as electroluminescent material.

The invention thus likewise relates to a PLED having one or more active layers, where at least one of these active layers comprises one or more polymers according to the invention. The active layer can be, for example, a light-emitting layer and/or a transport layer and/or a charge-injection layer and/or an interlayer.

The polymers according to the invention have the following surprising advantages over the polyspirobifluorenes and polyfluorenes described in WO 03/020790 A2 and WO 02/077060 A1, which are hereby mentioned as closest prior art:
(1) It has been found that the polymers according to the invention (with otherwise identical or similar composition) have higher luminous efficiencies in the application. This applies in particular to the copolymers which exhibit blue emission. This is of enormous importance since either the same brightness can thus be achieved with lower energy consumption, which is very important, in particular, in mobile applications (displays for cellphones, pagers, PDAs, etc.) which rely on batteries. Conversely, higher brightnesses are achieved with the same energy consumption, which may be interesting, for example, for illumination applications.
(2) Furthermore, it has surprisingly been found that, again in direct comparison, the polymers according to the invention have longer operating lifetimes, in particular in the case of green- and blue-emitting PLEDs.
(3) The polymers according to the invention are also equivalent to the known polymers with respect to solubility behaviour (for example gelling temperature at a given concentration, viscosity at a given concentration) or in some cases have better solubility in a wider range of solvents and are therefore just as suitable or more highly suitable for processing from solution, for example by printing techniques.
(4) The accessibility and achievability of colours are equivalent or better in the case of the polymers according to the invention compared with the prior art. In particular in the case of blue-emitting polymers, an improved colour location and a more saturated blue emission are observed.
(5) The polymers according to the invention are good electron conductors, even without the use of electron-conducting comonomers. Electron-conducting properties in polymers have hitherto been difficult to achieve since many electron conductors in accordance with the prior art are not sufficiently stable for high-quality applications.
(6) Since the novel polymer backbone of the formula (1) itself results in dark-blue emission, it is readily possible to introduce certain emitting units, which then still result in blue emission in the polymer. It is thereby readily possible to separate charge-transport and emission properties in the polymer. This appears necessary in order to obtain stable polymers. However, this was hitherto only possible with difficulty since the polymer backbone itself has always also emitted at the same time.

The present application text and also the examples below are directed to the use of polymers or blends according to the invention in relation to PLEDs and the corresponding displays. In spite of this restriction of the description, it is possible for the person skilled in the art, without further inventive step, also to use the polymers according to the invention for further uses in other electronic devices, for example for organic integrated circuits (O-ICs), organic field-effect transistors (OFETs), organic thin-film transistors (OTFTs), organic solar cells (O-SCs) or organic laser diodes (O-lasers), to mention but a few applications.

The present invention likewise relates to the use of polymers according to the invention in the corresponding devices and to these devices themselves.

The present invention is explained in greater detail below with reference to working examples, but without being restricted thereby.

### EXAMPLES

### Example 1

### Synthesis of 3,6-dibromo-9,10-dimethylphenanthrene

### a) Synthesis of 3,6-dibromo-9,10-dihydroxy-9,10-dimethyl-9,10-dihydrophenanthrene

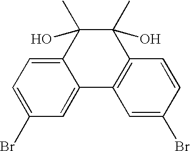

34.3 g (94 mmol) of 3,6-dibromophenanthrene-9,10-quinone are suspended in 600 ml of dry THF at −10° C. under argon, and 141 ml (282 mmol) of methylmagnesium chloride (2 molar solution in THF) are added dropwise at such a rate that the internal temperature does not exceed 0° C. The mixture is subsequently stirred overnight at room temperature. 50 ml of glacial acetic acid are added to the batch with ice-cooling, and the batch is diluted with ethyl acetate. After washing twice with saturated sodium chloride solution, the mixture is dried over sodium sulfate, and the solvents are removed, giving the product, which is employed in the next step without further purification.

### b) Synthesis of 3,6-dibromo-9-keto-10,10-dimethyl-9,10-dihydrophenanthrene

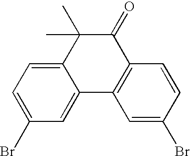

132.8 g (294 mmol) of 3,6-dibromo-9,10-dihydroxy-9,10-dimethyl-9,10-dihydrophenanthrene are suspended in 420 ml of acetic acid and 210 ml of trifluoroacetic acid under argon and stirred under reflux for 3 hours. The mixture is stirred overnight at room temperature and filtered with suction, the residue is washed with water and methanol and dissolved in toluene, the solution is filtered through silica gel, and the solvent is removed, giving the product, which is employed in the next step without further purification.

### c) Synthesis of 3,6-dibromo-9-hydroxy-10,10-dimethyl-9,10-dihydrophenanthrene

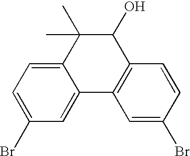

2.16 g (57 mmol) of lithium aluminium hydride are introduced into a flask which has been dried by heating. 100 ml of THF are added with ice-cooling. 43.4 g (114 mmol) of 3,6-dibromo-9-keto-10,10-dimethyl-9,10-dihydrophenanthrene in 150 ml of THF are then added dropwise, and the mixture is subsequently refluxed. The mixture is allowed to cool to room temperature overnight, then 2 ml of water are carefully added. After stirring for 15 minutes, 2 ml of 15% NaOH are added, the mixture is stirred for 15 minutes, 6 ml of water are added dropwise, and the mixture is stirred for 15 minutes. The resultant solid is filtered off with suction and washed with THF, and the solvent is removed from the filtrate, giving the product, which is employed in the next step without further purification.

### d) Synthesis of 3,6-dibromo-9,10-dimethylphenanthrene

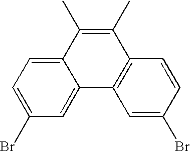

43.4 g (113 mmol) of 3,6-dibromo-9-hydroxy-10,10-dimethyl-9,10-dihydrophenanthrene are suspended in 610 ml of acetic acid. 780 mg of iodine and 3.5 ml of HBr in acetic acid are added, and the suspension is refluxed. The mixture is allowed to cool with stirring overnight. The product is obtained by filtering off the residue with suction and washing with water and methanol.

### Example 2

### Synthesis of 3,6-dibromo-9,10-bis(4-tert-butylphenyl)phenanthrene

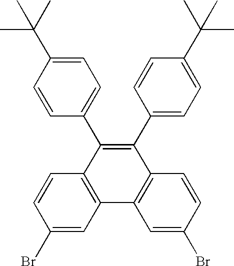

The synthesis is carried out analogously to Example 1 using 4-tent-butyl-phenylmagnesium chloride instead of methylmagnesium chloride. The product is purified by repeated recrystallisation from toluene and from chlorobenzene.

### Example 3

### Synthesis of the Polymers

The polymers are synthesised by SUZUKI coupling as described in WO 03/048225. The composition of synthesised polymers P1 to P3 is shown in Table 1. In addition, comparative polymers C1 and C2, which comprise monomers M4 and/or M5 instead of monomers M1 and M2, which result in units of the formula (1) in the polymer, are synthesised. The composition of these comparative polymers is likewise shown in Table 1.

### Example 4

### Production of the PLEDs

The polymers are investigated for use in PLEDs. The PLEDs are in each case two-layer systems, i.e. substrate/ITO/PEDOT/polymer/cathode. PEDOT is a polythiophene derivative (Baytron P, from H.C. Starck, Goslar). The cathode used in all cases is Ba/Ag (Aldrich). The way in which PLEDs are produced is described in detail in WO 04/037887 and the literature cited therein.

### Examples 5 to 9

### Device Examples

The results obtained on use of polymers P1 to P3 in PLEDs are shown in Table 1. Also shown are the electroluminescence results obtained using comparative polymers C1 to C2.

TABLE 1
Device results with polymers according to the invention and comparative polymers

| | | Monomer for | | | | | |
|---|---|---|---|---|---|---|---|
| | | units of the formula | | Max. eff./ | U @ | | |
| Example | Polymer | (1) | Further monomers | cd/A | 100 cd/m²/V | CIE x/y^{a} | Lifetime^{b}/h |
| 5 | P1 | 10% of M1 | 50% of M3, 30% of M4, | 4.30 | 4.6 | 0.15/0.15 | 300 |
| | | | 10% of M6 | | | | |
| 6 | P2 | 10% of M2 | 50% of M3, 20% of M4, | 5.50 | 4.0 | 0.16/0.21 | 910 |
| | | | 10% of M6, 10% of M5 | | | | |
| 7 | P3 | 30% of M2 | 50% of M3, 10% of M6, | 4.64 | 4.1 | 0.15/0.18 | 700 |
| | | | 10% of M5 | | | | |
| 8 | C1 | — | 50% of M3, 40% of M4, | 2.86 | 4.4 | 0.16/0.18 | 80 |
| (comparison) | | | 10% of M6 | | | | |
| 9 | C2 | — | 50% of M3, 30% of M4, | 4.66 | 3.9 | 0.17/0.30 | 530 |
| (comparison) | | | 10% of M6, 10% of M5 | | | | |

1-27. (canceled)

28. A polymer comprising at least 5 mol % of units of formula (1) 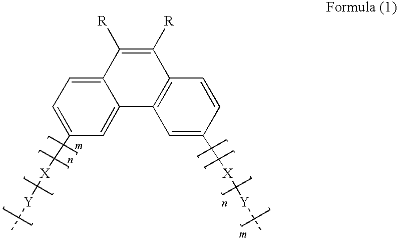
wherein
R on each occurrence, identically or differently, is H, a straight-chain, branched, or cyclic alkyl chain having up to 40 C atoms optionally substituted by R¹, wherein one or more non-adjacent C atoms are optionally replaced by ═N—R¹, —O—, —S—, —O—CO—O—, —CO—O—, —CR¹═CR¹—, or —C≡C— and wherein one or more H atoms are optionally replaced by F, Cl, Br, I, CN, or an aromatic or heteroaromatic ring system having 2 to 40 C atoms optionally substituted by one or more R¹; and wherein both R groups optionally define a further mono- or polycyclic, aromatic or aliphatic ring system;
X on each occurrence, identically or differently, is —CR¹═CR¹—, —C≡C—, or ═N—Ar—;
Y on each occurrence, identically or differently, is a divalent aromatic or heteroaromatic ring system having 2 to 40 C atoms optionally substituted by one or more R¹;
R¹ on each occurrence, identically or differently, is H, a straight-chain, branched or cyclic alkyl or alkoxy chain having up to 22 C atoms, wherein one or more non-adjacent C atoms are optionally replaced by ═N—R², —O—, —S—, —O—CO—O—, —CO—O—, —CR²═CR²—, or —C≡C—, and wherein one or more H atoms are optionally replaced by F, Cl, Br, I, CN, or an aryl, heteroaryl, aryloxy or heteroaryloxy group having 5 to 40 C atoms optionally substituted by one or more non-aromatic R²; F, Cl, Br, I, CN, N(R²)₂, Si(R²)₃, or B(R²)₂; and wherein two or more R¹ optionally define a ring system with one another and/or with R;
R² on each occurrence, identically or differently, is H or an aliphatic or aromatic hydrocarbon radical having up to 20 C atoms;
Ar on each occurrence, identically or differently, is a monovalent aromatic or heteroaromatic ring system having 2 to 40 C atoms optionally substituted by R¹;
n on each occurrence, identically or differently, is 0 or 1;
m on each occurrence, identically or differently, is 0, 1 or 2; and
the dashed bond is the link in the polymer.

29. The polymer of claim 28, wherein said polymer is conjugated or partially conjugated.

30. The polymer of claim 28, wherein said polymer comprises further structural elements in addition to the units of formula (1).

31. The polymer of claim 30, wherein said further structural elements increase hole-injection and/or -transport properties and are structural elements selected from the group consisting of triarylamine, benzidine, tetraaryl-para-phenylenediamine, triarylphosphine, phenothiazine, phenoxazine, dihydrophenazine, thianthrene, dibenzo-para-dioxin, phenoxathiyne, carbazole, azulene, thiophene, pyrrole and furan derivatives, and further O-, S- or N-containing heterocycles having a high HOMO.

32. The polymer of claim 30, wherein said further structural elements increase electron-injection and/or -transport properties and are selected from the group consisting of pyridine, pyrimidine, pyridazine, pyrazine, oxadiazole, quinoline, quinoxaline, phenazine derivatives, triarylboranes, and further O-, S- or N-containing heterocycles having a low LUMO.

33. The polymer of claim 30, wherein said further structural elements are combinations of structural elements selected from the group consisting of triarylamine, benzidine, tetraaryl-para-phenylenediamine, triarylphosphine, phenothiazine, phenoxazine, dihydrophenazine, thianthrene, dibenzo-para-dioxin, phenoxathiyne, carbazole, azulene, thiophene, pyrrole and furan derivatives, and further O-, S- or N-containing heterocycles having a high HOMO.

34. The polymer of claim 30, wherein said further structural elements change the emission characteristics to such an extent that electrophosphorescence can be obtained instead of electrofluorescence.

35. The polymer of claim 30, wherein said further structural elements improve the transition from the singlet state to the triplet state and are selected from the group consisting of carbazole and bridged carbazole dimer units, ketones, phosphine oxides, sulfoxides, sulfones, and silane derivatives.

36. The polymer of claim 30, wherein said further structural elements influence the morphology and/or the emission colour of the polymers and are selected from the group consisting of 1,4-phenylene derivatives; 1,4-naphthylene derivatives; 1,4- or 9,10-anthrylene derivatives; 1,6-, 2,7- or 4,9-pyrenylene derivatives; 3,9- or 3,10-perylenylene derivatives; 4,4′-biphenylylene derivatives; 4,4″-terphenylylene derivatives, 4,4′-bi-1,1′-naphthylylene derivatives; 4,4′-tolanylene derivatives; 4,4′-stilbenzylene derivatives; and 4,4″-bisstyrylarylene derivatives.

37. The polymer of claim 30, wherein said further structural elements are typically used as backbone and are selected from the group consisting of 4,5-dihydropyrene derivatives; 4,5,9,10-tetrahydropyrene derivatives; fluorene derivatives, 9,9′-spirobifluorene derivatives; 9,10-dihydrophenanthrene derivatives; 5,7-dihydrodibenzooxepine derivatives; and cis- and trans-indenofluorene derivatives.

38. The polymer of claim 28, wherein said polymer comprises at least 10 mol % of units of formula (1).

39. The polymer of claim 30, wherein said further structural elements comprise at least two different structural units selected from the group consisting of triarylamine, benzidine, tetraaryl-para-phenylenediamine, triarylphosphine, phenothiazine, phenoxazine, dihydrophenazine, thianthrene, dibenzo-para-dioxin, phenoxathiyne, carbazole, azulene, thiophene, pyrrole and furan derivatives, further O-, S- or N-containing heterocycles having a high HOMO.

40. The polymer of claim 28, wherein said polymer further comprises hole-conducting units and emitting units.

41. The polymer of claim 28, wherein said polymer comprises units of formula (1) as backbone and n on each occurrence is 0.

42. The polymer of claim 28, wherein said units of formula (1) are hole-transporting units and:
n on each occurrence, identically or differently, is 0 or 1, where at least one n=1;
m on each occurrence, identically or differently, is 0, 1 or 2, where m is not equal to 0 if the corresponding n=1; and
X on each occurrence is ═N—Ar—.

43. The polymer of claim 28, wherein said units of formula (1) are emitters and:
n on each occurrence, identically or differently, is 0 or 1, where at least one n=1;
m on each occurrence, identically or differently, is 0, 1 or 2, where m is not equal to 0 if the corresponding n=1; and
X on each occurrence, identically or differently, is —CR¹═CR¹—, —C≡C—, or ═N—Ar—, wherein at least one X is equal to —CR¹═CR¹— or —C≡C—.

44. The polymer of claim 28, wherein said units of formula (1) are symmetrically substituted in the 9,10-positions of the phenanthrene units.

45. The polymer of claim 28, wherein said polymer is prepared by SUZUKI polymerisation, YAMAMOTO polymerisation, STILLE polymerisation, or HARTWIG-BUCHWALD polymerisation.

46. A compound of formula (2) 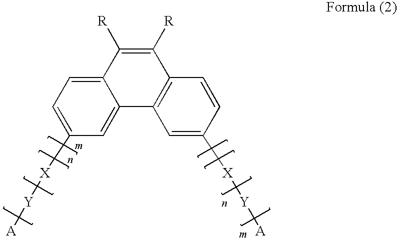
wherein each A is identical or different and copolymerises under C—C or C—N linking reaction conditions; and wherein
R on each occurrence, identically or differently, is H, a straight-chain, branched, or cyclic alkyl chain having up to 40 C atoms optionally substituted by R¹, wherein one or more non-adjacent C atoms are optionally replaced by ═N—R¹, —O—, —S—, —O—CO—O—, —CO—O—, —CR¹═CR¹—, or —C≡C— and wherein one or more H atoms are optionally replaced by F, Cl, Br, I, CN, or an aromatic or heteroaromatic ring system having 2 to 40 C atoms optionally substituted by one or more R¹; and wherein both R groups optionally define a further mono- or polycyclic, aromatic or aliphatic ring system;
X on each occurrence, identically or differently, is —CR¹═CR¹—, —C≡C—, or ═N—Ar—;
Y on each occurrence, identically or differently, is a divalent aromatic or heteroaromatic ring system having 2 to 40 C atoms optionally substituted by one or more R¹;
R¹ on each occurrence, identically or differently, is H, a straight-chain, branched or cyclic alkyl or alkoxy chain having up to 22 C atoms, wherein one or more non-adjacent C atoms are optionally replaced by ═N—R², —O—, —S—, —O—CO—O—, —CO—O—, —CR²═CR²—, or —C≡C— and wherein one or more H atoms are optionally replaced by F, Cl, Br, I, CN, or an aryl, heteroaryl, aryloxy or heteroaryloxy group having 5 to 40 C atoms optionally substituted by one or more non-aromatic R²; F, Cl, Br, I, CN, N(R²)₂, Si(R²)₃, or B(R²)₂; and wherein two or more R¹ optionally define a ring system with one another and/or with R;
R² on each occurrence, identically or differently, is H or an aliphatic or aromatic hydrocarbon radical having up to 20 C atoms;
Ar on each occurrence, identically or differently, is a monovalent aromatic or heteroaromatic ring system having 2 to 40 C atoms optionally substituted by R¹;
n on each occurrence, identically or differently, is 0 or 1;
m on each occurrence, identically or differently, is 0, 1 or 2; and
the dashed bond is the link in the polymer.

47. The compound of claim 46, wherein A is selected from the group consisting of Cl, Br, I, O-tosylate, O-triflate, O—SO₂R², B(OR²)₂, and Sn(R²)₃, where R² on each occurrence, identically or differently, is H or an aliphatic or aromatic hydrocarbon radical having up to 20 C atoms; and wherein two or more R² optionally define a ring system.

48. The compound of claim 46, wherein said C—C linking reaction conditions are selected from the group consisting of SUZUKI coupling, YAMAMOTO coupling, and STILE coupling, and said C—N linking reaction condition is a HARTWIG-BUCHWALD coupling.

49. A blend of one or more polymers of claim 28 with further polymeric, oligomeric, dendritic, and/or low-molecular-weight substances.

50. A solution or formulation comprising one or more polymers according to claim 28 in one or more solvents.

51. An organic electronic component having one or more active layers, wherein at least one of said one or more active layers comprises one or more polymers according to claim 28.

52. The organic electronic component of claim 51, wherein said organic electronic component is a polymeric light-emitting diode, organic integrated circuit, organic field-effect transistor, organic thin-film transistor, organic solar cell, or organic laser diode.

53. The organic electronic component of claim 52, wherein said organic electronic component is a polymeric light-emitting diode.
